(19) United States
(12) Patent Application Publication
(10) Pub. No.: US 2025/0143128 A1
(43) Pub. Date: May 1, 2025

(54) DISPLAY DEVICE AND METHOD OF MANUFACTURING THE DISPLAY DEVICE

(71) Applicant: Samsung Display Co., LTD., Yongin-si (KR)

(72) Inventor: Dong Jin KANG, Yongin-si (KR)

(21) Appl. No.: 18/742,910

(22) Filed: Jun. 13, 2024

(30) Foreign Application Priority Data
Oct. 25, 2023 (KR) 10-2023-0144227

(51) Int. Cl. H10K 59/35; H10K 50/115; H10K 71/13

(52) U.S. Cl. CPC H10K 59/353; H10K 50/115; H10K 71/135

(57) ABSTRACT

A display device and a method of manufacturing the display device are provided. The display device includes sub-pixels including a first sub-pixel forming a first sub-pixel area providing light of a first color, a second sub-pixel forming a second sub-pixel area providing light of a second color, and a third sub-pixel forming a third sub-pixel area providing light of a third color. The third sub-pixel area is larger than each of the first sub-pixel area and the second sub-pixel area. Each of the first sub-pixel and the second sub-pixel includes a quantum dot light emitting element including a quantum dot light emitting layer. The third sub-pixel includes an organic light emitting element including an organic light emitting element layer.

### CROSS-REFERENCE TO RELATED APPLICATION

This application claims priority to Korean Patent Application No. 10-2023-0144227, filed on Oct. 25, 2023, and all the benefits accruing therefrom under 35 U.S.C. § 119, the content of which in its entirety is herein incorporated by reference.

### BACKGROUND

### (a) Field

The present disclosure relates to a display device and a method of manufacturing the display device.

### (b) Description of the Related Art

Recently, as interest in information displays is increasing, research and development for display devices are continuously conducted.

The display device is a self-luminous element and may include a light emitting diode including a hole transport portion, an electron transport portion, and a light emitting layer between the hole transport portion and the electron transport portion. Holes provided from the hole transport portion and electrons provided from the electron transport portion may be recombined in the light emitting layer to generate excitons. Light may be generated when the generated excitons change from the excited state to the ground state.

The light emitting layer of the light emitting element may include an organic light emitting layer using an organic material and/or a quantum dot light emitting layer including a quantum dot material. In some cases, since the organic light emitting layer and the quantum dot light emitting layer include materials with different physical properties, it may be substantially difficult to form a light emitting structure simultaneously including the organic light emitting layer and the quantum dot light emitting layer, while sufficiently securing target process characteristics associated with the light emitting structure.

Accordingly, methods for efficiently providing a light emitting structure including an organic light emitting layer and a quantum dot light emitting layer are desired.

### SUMMARY

An aspect of the present disclosure provides a display device and a method of manufacturing the display device in which light emitting structures including an organic light emitting layer and a quantum dot light emitting layer may be efficiently prepared.

An embodiment of the present disclosure provides a display device including: sub-pixels including a first sub-pixel forming a first sub-pixel area providing light of a first color, a second sub-pixel forming a second sub-pixel area providing light of a second color, and a third sub-pixel forming a third sub-pixel area providing light of a third color layers. The third sub-pixel area is larger than each of the first sub-pixel area and the second sub-pixel area. Each of the first sub-pixel and the second sub-pixel includes a quantum dot light emitting element including a quantum dot light emitting layer. The third sub-pixel includes an organic light emitting element including an organic light emitting element layer.

The second sub-pixel area may be larger than the first sub-pixel area,

The first sub-pixel may be a red sub-pixel. The second sub-pixel may be a green sub-pixel. The third sub-pixel may be a blue sub-pixel.

The quantum dot light emitting layer included in the quantum dot light emitting element included in the first sub-pixel may include a first quantum dot light emitting layer. The quantum dot light emitting layer included in the quantum dot light emitting element included in the second sub-pixel may include a second quantum dot light emitting layer. The organic light emitting layer, the first quantum dot light emitting layer, and the second quantum dot light emitting layer may be of a same thickness.

The display device may further include a bank surrounding a first area in which the quantum dot light emitting layer and the organic light emitting element of the first sub-pixel are disposed and a second area in which the quantum dot light emitting layer and the organic light emitting element of the second sub-pixel are disposed. The bank may form a first opening that overlaps the first sub-pixel area, a second opening that overlaps the second sub-pixel area, and a third opening that overlaps the third sub-pixel area.

The quantum dot light emitting layer may include a quantum dot compound. The organic light emitting layer may include an organic material.

Each of the quantum dot light emitting element included in the first sub-pixel, the quantum dot light emitting element included in the second sub-pixel, and the organic light emitting element may further include a first electrode, a hole transport portion, an electron transport portion, and a second electrode.

Another embodiment of the present disclosure provides a method of manufacturing a display device. The display device includes sub-pixels including a first sub-pixel forming a first sub-pixel area providing light of a first color, a second sub-pixel forming a second sub-pixel area providing light of a second color, and a third sub-pixel forming a third sub-pixel area providing light of a third color.

The method includes manufacturing a pixel circuit layer; patterning a bank on the pixel circuit layer; and manufacturing a light emitting layer within one or more openings formed by the bank. The one or more openings include a first opening in the first sub-pixel area, a second opening in the second sub-pixel area, and a third opening in the third sub-pixel area. The manufacturing of the light emitting layer includes manufacturing an organic light emitting layer within the third opening; manufacturing a second quantum dot light emitting layer within the second opening; and manufacturing a first quantum dot light emitting layer within the first opening. A third area of the third opening may be larger than each of a first area of the first opening and a second area of the second opening in a plan view. The manufacturing of the organic light emitting layer is performed before the manufacturing of the first quantum dot light emitting layer and the manufacturing of the second quantum dot light emitting layer.

The manufacturing of the light emitting layer may include performing an inkjet printing process.

The manufacturing of the organic light emitting layer may include ejecting ink for manufacturing the organic light emitting layer onto the pixel circuit layer. The manufacturing of the first quantum dot light emitting layer may include ejecting a first quantum dot ink onto the pixel circuit layer. The manufacturing of the second quantum dot light emitting layer may include ejecting a second quantum dot ink onto the pixel circuit layer.

The first quantum dot ink and the second quantum dot ink may include a same solvent.

Each of the first quantum dot ink, the second quantum dot ink, and the ink for manufacturing the organic light emitting layer may include two or more solvents.

Each of the first quantum dot ink, the second quantum dot ink, and the ink for manufacturing the organic light emitting layer may include an organic solvent.

A boiling point of the ink for manufacturing the organic light emitting layer may be lower than respective boiling points of the first quantum dot ink and the second quantum dot ink.

The manufacturing of the light emitting layer may include drying a solvent of each of the first quantum dot ink, the second quantum dot ink, and the ink for manufacturing the organic light emitting layer. The drying of the solvent may be performed in a temperature range of 25° C. to 75° C. and in a vacuum environment.

The manufacturing of the second quantum dot light emitting layer may be performed after the manufacturing of the organic light emitting layer is performed. The manufacturing of the first quantum dot light emitting layer may be performed after the manufacturing of the second quantum dot light emitting layer is performed.

Each of the first quantum dot light emitting layer and the second quantum dot light emitting layer may include a quantum dot compound. The organic light emitting layer may include an organic material. The organic light emitting layer, the first quantum dot light emitting layer, and the second quantum dot light emitting layer may be of a same thickness.

According to one or more embodiments of the present disclosure of the present disclosure, a display device and a method of manufacturing the display device are provided in which light emitting structures including an organic light emitting layer and a quantum dot light emitting layer may be efficiently prepared.

### BRIEF DESCRIPTION OF THE DRAWINGS

FIG. 1 illustrates a schematic top plan view of a display device according to an embodiment.

FIG. 2 illustrates a schematic cross-sectional view of a display device according to an embodiment.

FIG. 3 illustrates a schematic flowchart of a method of manufacturing a display device according to an embodiment.

FIG. 4 illustrates a schematic flowchart of steps for manufacturing a light emitting layer according to an embodiment.

FIG. 5 to FIG. 10 illustrate cross-sectional views of process steps of a method of manufacturing a display device according to an embodiment.

### DETAILED DESCRIPTION

Since the present disclosure may be variously modified and have various forms, embodiments will be illustrated and described in detail in the following. This, however, by no means restricts aspects of the present disclosure to the specific embodiments, and aspects of the present disclosure are to be understood as embracing all included in the spirit and scope of the present disclosure changes, equivalents, and substitutes.

Terms such as, for example, first, second, and the like will be used to describe various constituent elements, and are not to be interpreted as limiting these constituent elements. These terms are used to differentiate one constituent element from another. For example, a first constituent element may be referred to as a second constituent element, and similarly, a second constituent element may be referred to as a first constituent element, without departing from the scope of the present disclosure. Singular forms are intended to include plural forms unless the context clearly indicates otherwise.

In the present disclosure, it should be understood that the terms “include”, “comprise”, “have”, or “configure” indicate that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that when an element such as, for example, a layer, film, region, area, or substrate is referred to as being “on” another element, the element can be directly on the other element or intervening elements may also be present. In some aspects, in the present specification, when a portion of a layer, film, region, area, plate, or the like is referred to as being formed “on” another portion, the formed direction is not limited to an upper direction but includes a lateral or lower direction. In contrast, when an element of a layer, film, region, area, plate, or the like is referred to as being “below” another element, the element may be directly below the other element, or intervening elements may be present.

The term “substantially,” as used herein, means approximately or actually. The term “substantially equal,” as used herein, means approximately or actually equal (e.g., within a threshold percent of equal). The term “substantially the same,” as used herein, means approximately or actually the same (e.g., within a threshold difference amount).

The present disclosure relates to a display device and a method of manufacturing the display device. Hereinafter, a display device according to an embodiment will be described with reference to the accompanying drawings.

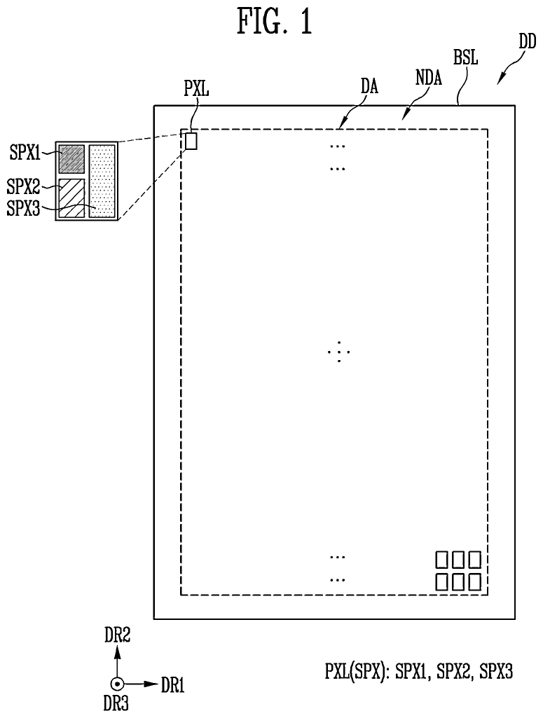

FIG. 1 illustrates a schematic top plan view of a display device according to an embodiment.

Referring to FIG. 1, a display device DD may include a base layer BSL, and a pixel PXL disposed on the base layer BSL. Although not shown in FIG. 1, the display device DD may further include a driving circuit part (for example, a scan driver and a data driver) for driving the pixel PXL, wires, and pads.

The display device DD (or the base layer BSL) may include a display area DA and a non-display area NDA. The non-display area NDA may mean an area other than the display area DA. The non-display area NDA may surround at least a portion of the display area DA.

The base layer BSL may form or serve as a base surface of the display device DD. The base layer BSL may be a rigid or flexible substrate or film. For example, the base layer BSL may include a glass material. Alternatively or additionally, the base layer BSL may include a silicon material. Alternatively or additionally, the base layer BSL may include polyimide. However, embodiments of the present disclosure are not limited thereto.

The display area DA may mean an area in which the pixels PXL are disposed. The non-display area NDA may mean an area in which the pixel PXL is not disposed. In the non-display area NDA, a driving circuit portion, wires, and pads connected to the pixel PXL of the display area DA may be disposed.

According to one or more embodiments of the present disclosure, the pixels PXL (or sub-pixels SPX) may be arranged in various structures. For example, the pixels PXL (or the sub-pixels SPX) may be arranged according to a stripe (for example, an S-stripe) or PENTILE™ arrangement structure.

For example, FIG. 1 illustrates a structure in which the pixels PXL (or the sub-pixels SPX) are arranged in an S-stripe structure. For example, a third sub-pixel SPX3 may be adjacent to first and second sub-pixels SPX1 and SPX2 in a first direction DR1, and the first and second sub-pixels SPX1 and SPX2 may be adjacent in a second direction DR2.

According to one or more embodiments of the present disclosure, the pixel PXL (or the sub-pixels SPX) may include the first sub-pixel SPX1, the second sub-pixel SPX2, and the third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit capable of emitting light of one or more various colors.

Each of the first sub-pixel SPX1, the second sub-pixel SPX2, and the third sub-pixel SPX3 may emit light of a color.

For example, the first sub-pixel SPX1 may be a red sub-pixel emitting red (for example, first color) light, the second sub-pixel SPX2 may be a green sub-pixel emitting green (for example, second color) light, and the third sub-pixel SPX3 may be a blue sub-pixel emitting blue (for example, third color) light. The red sub-pixel may emit light in a wavelength band of 600 nm to 750 nm. The green sub-pixel may emit light in a wavelength band of 480 nm to 560 nm. The blue sub-pixel may emit light in a wavelength band of 370 nm to 460 nm.

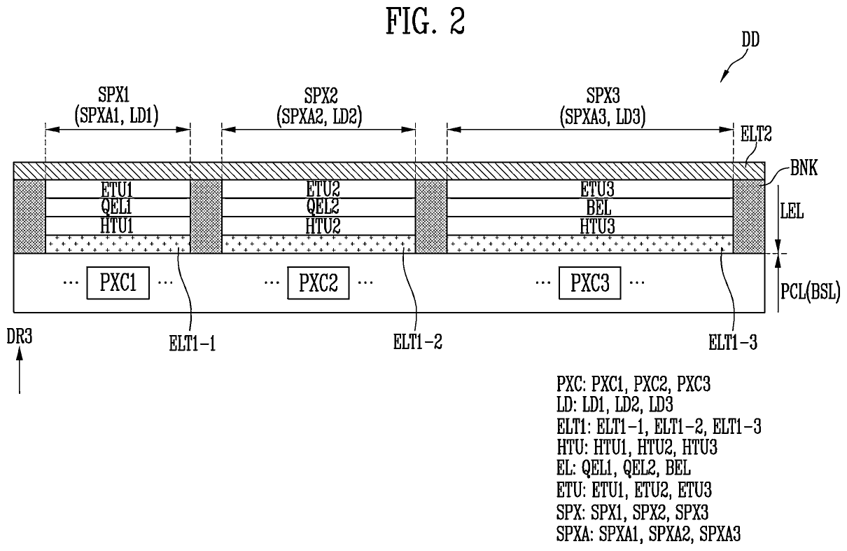

According to one or more embodiments of the present disclosure, the sub-pixels SPX may be of different sizes. For example, based on the type of light emitting elements LD (see FIG. 2) included in each of the sub-pixels SPX, the sizes of the sub-pixels SPX may be different from each other. For example, the third sub-pixel SPX3 may be larger than each of the first and second sub-pixels SPX1 and SPX2. In some embodiments, the second sub-pixel SPX2 may be larger than the first sub-pixel SPX1. Aspects of the sub-pixels SPX will be described in detail later with reference to FIG. 2.

FIG. 2 illustrates a schematic cross-sectional view of a display device according to an embodiment.

Referring to FIG. 2, the display device DD may include a pixel circuit layer PCL including the base layer BSL and a light emitting element layer LEL on the pixel circuit layer PCL. The sub-pixel SPX of the display device DD may form a sub-pixel area SPXA. The sub-pixel area SPXA may include a first sub-pixel area SPXA1 in which light of the first color is provided, a second sub-pixel area SPXA2 in which light of the second color is provided, and a third sub-pixel area SPXA3 in which light of the third color is provided.

The base layer BSL may form a base on which a pixel circuit PXC is disposed. The pixel circuit PXC may be disposed on the base layer BSL and may be configured to drive the light emitting element LD. The pixel circuit layer PCL may include conductive layers and insulating layers, and the conductive layers may form the pixel circuit PXC. The pixel circuit PXC may include circuit elements capable of driving the sub-pixel SPX (or the light emitting element LD). The circuit elements may include a driving transistor, and in some aspects may include additional transistors and capacitors.

The pixel circuit PXC may include a first pixel circuit PXC1 electrically connected to a first light emitting element LD1 disposed in the first sub-pixel area SPXA1, a second pixel circuit PXC2 electrically connected to a second light emitting element LD2 disposed in the second sub-pixel area SPXA2, and a third pixel circuit PXC3 electrically connected to a third light emitting element LD3 disposed in the third sub-pixel area SPXA3.

The light emitting element layer LEL may be disposed on the pixel circuit layer PCL. In some embodiments, the light emitting element layer LEL may include the light emitting element LD. In some embodiments, the light emitting element layer LEL may further include a bank BNK.

The light emitting element LD may include the first light emitting element LD1 included in the first sub-pixel SPX1 and disposed in the first sub-pixel area SPXA1, the second light emitting element LD2 included in the second sub-pixel SPX2 and disposed in the second sub-pixel area SPXA2, and the third light emitting element LD3 included in the third sub-pixel SPX3 and disposed in the third sub-pixel area SPXA3.

The light emitting element LD may include a first electrode ELT1, a hole transport portion HTU, a light emitting layer EL, an electron transport portion ETU, and a second electrode ELT2.

The first electrode ELT1 may be disposed on the pixel circuit layer PCL. The first electrode EL1 may be an anode electrode. The first electrode ELT1 may include a (1-1)-th electrode ELT1-1 included in the first light emitting element LD1, a (1-2)-th electrode ELT1-2 included in the second light emitting element LD2, and a (1-3)-th electrode ELT1-3 included in the third light emitting element LD3. The (1-1)-th electrode ELT1-1, the (1-2)-th electrode ELT1-2, and the (1-3)-th electrode ELT1-3 may be spaced apart from each other in association with forming anode electrodes for different sub-pixels SPX.

In some embodiments, the first electrode ELT1 may include various conductive materials. For example, the first electrode ELT1 may include at least one of gold (Au), silver (Ag), aluminum (Al), molybdenum (Mo), chromium (Cr), titanium (Ti), nickel (Ni), neodymium (Nd), copper (Cu), and platinum (Pt), and in some embodiments, the first electrode ELT1 may include a transparent conductive material.

The hole transport portion HTU is configured to transport holes. In some embodiments, the hole transport portion HTU may include various hole transport organic materials, and the hole transport portion HTU may further include a p-dopant, a known spin-coated polymer, and the like. The hole transport portion HTU may include a multi-layered structure having a plurality of layers each containing different materials. For example, the hole transport portion HTU may include at least one of a hole injection layer and a hole transport layer, and in some embodiments, the hole transport portion HTU may further include a light emitting auxiliary layer and an electron blocking layer.

A hole injection layer may be a layer that performs or improves a hole injection function from the anode electrode to another adjacent layer. A hole transport layer may be a layer that provides provided holes to the light emitting layer EL. The light emitting auxiliary layer may be a layer that compensates for a resonance distance based on a wavelength of light provided by the light emitting layer EL (e.g., light transmitted through the light emitting layer EL). The electron blocking layer may be a layer that may prevent electrons from being injected from the electron transport portion ETU to reduce the number of carriers (for example, holes or electrons) leaving the light emitting layer EL.

The hole transport portion HTU may include a first hole transport portion HTU1 included in the first light emitting element LD1, a second hole transport portion HTU2 included in the second light emitting element LD2, and a third hole transport portion HTU3 included in the third light emitting element LD3. In some embodiments, the first to third hole transport portions HTU1 to HTU3 may include at least some of the same layers. However, embodiments of the present disclosure are not limited thereto.

The light emitting layer EL may generate light based on a current applied to the light emitting layer EL. The light emitting layer EL may be disposed between the hole transport portion HTU and the electron transport portion ETU.

The light emitting layer EL may include a material that may emit light of a color. The light emitting layer EL may include at least some different materials for each of the sub-pixels SPX. For example, the light emitting layer EL may include an organic light emitting layer BEL and one or more quantum dot light emitting layers QEL. In some embodiments, the first light emitting element LD1 and the second light emitting element LD2 may include quantum dot light emitting layers QEL1 and QEL2. The third light emitting element LD3 may include an organic light emitting layer BEL. Accordingly, for example, the display device DD may form a hybrid light emitting structure including two or more different materials.

The organic light emitting layer BEL may include an organic material. The organic light emitting layer BEL may include a host and a dopant. The host of the organic light emitting layer BEL is a light emitting material that may capture carriers (electrons and holes) for light generation, and may induce excitons to be efficiently generated. The dopant of the organic light emitting layer BEL may include a phosphorescent dopant or a fluorescent dopant. In some embodiments, examples of the dopant are not particularly limited. In some embodiments, the dopant may include an organic material or a metal complex.

The first and second quantum dot light emitting layers QEL1, and QEL2 may include a quantum dot compound. For example, the quantum dot compound may include a crystal of a semiconductor compound. For example, the quantum dot compound may include a semiconductor material selected from a group III-VI semiconductor compound, a group II-VI semiconductor compound, a group III-V semiconductor compound, a group IV-VI semiconductor compound, a group IV element or compound, or a combination thereof. However, embodiments of the present disclosure are not particularly limited thereto. A diameter of the quantum dot compound is not particularly limited, and since an energy band gap may be adjusted by adjusting a size of the quantum dot compound, the first and second quantum dot light emitting layers QEL1 and QEL2 may be configured to emit light of a color (e.g., by adjusting the size of the quantum dot compound).

In some embodiments, a thickness of the quantum dot light emitting layer QEL1, a thickness of the quantum dot light emitting layer EL2, and a thickness of the organic light emitting layer BEL may be substantially similar to each other. For example, the thickness of the quantum dot light emitting layer QEL1, thickness of the quantum dot light emitting layer QEL2, and the thickness of the organic light emitting layer BEL may be equal. Expressed another way, the quantum dot light emitting layer QEL1, the quantum dot light emitting layer EL2, and the organic light emitting layer BEL may be of a same thickness.

In some embodiments, the quantum dot light emitting layers QEL1 and QEL2 and the organic light emitting layer BEL may be manufactured by using an inkjet printing process. The inkjet printing process according to the techniques described herein may be implemented with a relatively low cost, and thus may have excellent manufacturing efficiency.

However, when the quantum dot light emitting layers QEL1 and QEL2 and the organic light emitting layer BEL are manufactured by using the inkjet printing process, it may be substantially difficult to form the intended light emitting structure due to the difference in physical properties of the ink for manufacturing respective layers.

For example, experimentally, when the ink in the first formed sub-pixel SPX dries, there may be a risk that the material contained in the ink in the subsequently formed sub-pixel SPX may be damaged. Particularly, a threshold processing duration may be required for the quantum dot light emitting layers QEL1 and QEL2 to be properly self-assembled within the area in which the quantum dot light emitting layers QEL1 and QEL2 are to be disposed. In this case, as the ink for forming the quantum dot emitting layers QEL1 and QEL2 dries, there may be a risk that the organic material forming the organic emitting layer EL may be damaged.

However, according to one or more embodiments of the present disclosure, an area in which the quantum dot light emitting layers QEL1 and QEL2 are disposed may be larger than an area in which the organic light emitting layer BEL is disposed.

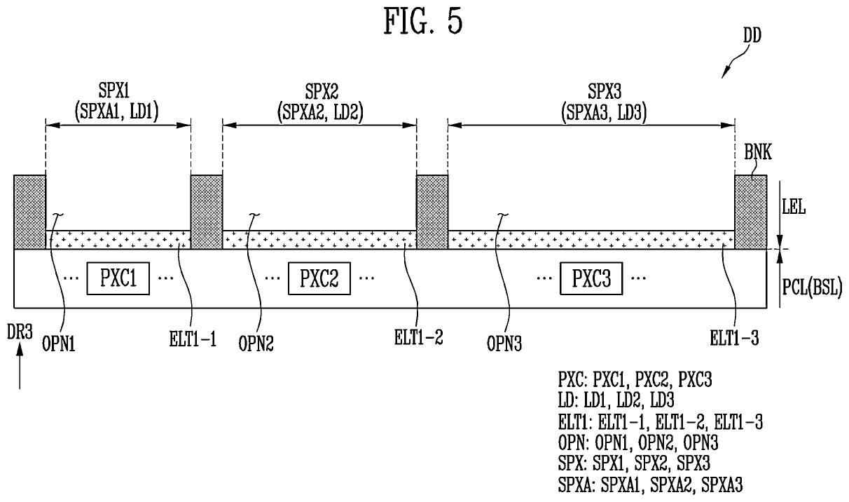

For example, the third sub-pixel SPX3 may have a larger area than each of the first and second sub-pixels SPX1 and SPX2. The third sub-pixel area SPXA3 may have a larger area than each of the first and second sub-pixel areas SPXA1 and SPXA2. In some embodiments, a third opening OPN3 (see FIG. 5) may be larger than each of first and second openings OPN1 and OPN2 (see FIG. 5). The second sub-pixel SPX2 may have a larger area than the first sub-pixel SPX1. The second sub-pixel area SPXA2 may have a larger area than the first sub-pixel area SPXA1. In some embodiments, the second opening OPN2 may be larger than the first opening OPN1.

Accordingly, for example, the organic light emitting layer BEL may be disposed such that the area of the organic light emitting layer BEL is wider than respective areas of the first and second quantum dot light emitting layers QEL1 and QEL2, and the second quantum dot light emitting layer QEL2 may be disposed such that the area of the second quantum dot light emitting layer QEL2 is wider than the area of the first quantum dot light emitting layer QEL1.

In this case, inks (hereinafter referred to as first quantum dot ink and second quantum dot ink, respectively) for manufacturing the first and second quantum dot light emitting layers QEL1 and QEL2 may be supplied to one or more areas (for example, the second and third openings OPN2 and OPN3) which are narrower compared to an area (for example, the first opening OPN1) in which ink (hereinafter referred to as ink for manufacturing an organic light emitting layer) for manufacturing the organic light emitting layer BEL is supplied. Accordingly, for example, the duration associated with drying the first quantum dot ink and the second quantum dot ink may be reduced, and as a result, the risk of damage to the organic light emitting layer BEL due to the first quantum dot ink and the second quantum dot ink may be reduced.

In some aspects, according to one or more embodiments of the present disclosure, the first and second quantum dot inks may have a higher boiling point than the ink for manufacturing the organic light emitting layer. In this case, when inkjet processes for manufacturing the light emitting layers EL are performed, the first and second quantum dot inks may dry faster than the ink for manufacturing the organic light emitting layer in a same time range. Accordingly, for example, as the first and second quantum dot inks dry, the risk of damaging the organic materials in the organic light emitting layer EL may be reduced.

In some aspects, according to one or more embodiments of the present disclosure, the sub-pixels SPX may be provided such that sizes of the sub-pixels SPX differ based on the material characteristics of the light emitting layer EL corresponding to respective sub-pixels SPX, and at the same time, the light emitting layers EL may be sequentially manufactured in the order of the areas SPXA with larger areas. That is, for example, the techniques described herein may include manufacturing the light emitting layers EL in an order based on respective sizes of the areas SPXA (e.g., in an order from largest to smallest).

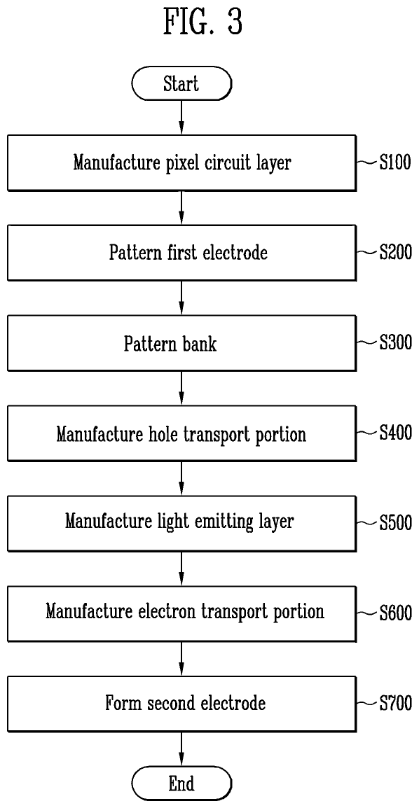

In this case, when the inkjet printing process for manufacturing the light emitting layers EL is performed in accordance with the techniques described herein, the risk of damaging the light emitting layers EL is prevented due to the characteristics of respective materials, such that the reliability of the element characteristics of the light emitting elements LD may be improved, and the thickness of the light emitting layers EL may be manufactured as intended (e.g., according to target thickness, uniformity, or the like). For example, the techniques described herein may include manufacturing the light emitting layers EL such that the thicknesses of the light emitting layers EL are substantially uniform for each of the sub-pixels SPX. Based on the techniques described herein, the inks for manufacturing the light emitting layer EL may be dried within a relatively similar drying time for each of the sub-pixels SPX. Example aspects of the inkjet printing process supported by aspects of the present disclosure will be described in conjunction with the description of the manufacturing method after FIG. 3.

The electron transport portion ETU is configured to transport electrons. In some embodiments, the electron transport portion ETU may include various electron transport materials. For example, the electron transport portion ETU may include a metal-free organic material, and in some aspects may include a metal-containing organic material or various metallic materials (for example, an alkaline earth metal and/or a rare earth metal, and the like). The electron transport portion ETU may include a multi-layered structure having a plurality of layers each containing different materials. For example, the electron transport portion ETU may include at least one of an electron injection layer and an electron transport layer, and in some embodiments, the electron transport portion ETU may further include an electron buffer layer and a hole blocking layer.

The electron injection layer may be a layer that performs or improves an electron injection function from the cathode electrode to another layer adjacent the electron injection layer. The electron transport layer may be a layer that provides provided electrons to the light emitting layer EL. The hole blocking layer may be a layer that may reduce the number of carriers leaving the light emitting layer EL by preventing holes from being injected from the hole transport portion HTU.

The electron transport portion ETU may include a first electron transport portion ETU1 included in the first light emitting element LD1, a second electron transport portion ETU2 included in the second light emitting element LD2, and a third electron transport portion ETU3 included in the third light emitting element LD3. In some embodiments, the first to third electron transport portions ETU1 to ETU3 may include at least some of the same layers. However, embodiments of the present disclosure are not limited thereto.

The second electrode ELT2 may be disposed on the first to third light emitting elements LD1 to LD3. The second electrode ELT2 may be disposed on the bank BNK. The second electrode ELT2 may be a cathode electrode. The second electrode ELT2 may be a common electrode included in each of the first to third light emitting elements LD1 to LD3.

The second electrode ELT2 may include transparent conductive materials such as, for example, an indium tin oxide (ITO), an indium zinc oxide (IZO), a zinc oxide (ZnOx), an indium gallium zinc oxide (IGZO), and an indium tin zinc oxide (ITZO). However, embodiments of the present disclosure are not limited thereto. The second electrode ELT2 may be or include a conductive material having somewhat reflective properties (e.g., reflective properties satisfying a threshold).

The bank BNK may be disposed on the pixel circuit layer PCL. The bank BNK may protrude in the thickness direction of the base layer BSL and may surround an area in a plan view. Accordingly, for example, the bank BNK may form an opening OPN.

The opening OPN formed by the bank BNK may be an area in which ink may be accommodated when an inkjet printing process for manufacturing the light emitting layer EL or the like is performed.

As described herein, the bank BNK may form openings OPN having different sizes. Accordingly, for example, aspects of the inkjet printing process may include depositing ink into the openings OPN of different sizes. Accordingly, for example, the light emitting layers EL may be formed in different openings OPN for each of the sub-pixels SPX to be provided, respectively.

The bank BNK may include an organic material. For example, the bank BNK may include one or more of an acrylic resin, an epoxy resin, a phenol resin, a polyamide resin, and a polyimide resin. However, embodiments of the present disclosure are not limited thereto.

Hereinafter, a manufacturing method of the display device DD according to one or more embodiments of the present disclosure will be described with reference to FIG. 3 to FIG. 10. Descriptions that may be redundant to those described herein are simplified or are not repeated.

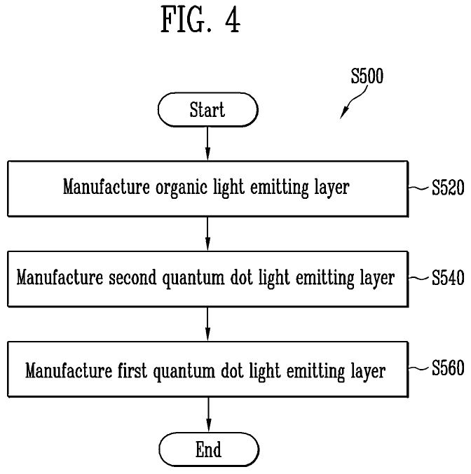

FIG. 3 illustrates a schematic flowchart of a method of manufacturing a display device according to an embodiment. FIG. 4 illustrates a schematic flowchart of steps for manufacturing a light emitting layer according to an embodiment.

FIG. 5 to FIG. 10 illustrate cross-sectional views of process steps of a method of manufacturing a display device according to one or more embodiments. FIG. 5 to FIG. 10 illustrate process steps, respectively, based on a cross-sectional structure of the display device DD described herein with reference to FIG. 2.

In the descriptions of the methods herein, the operations (steps) may be performed in a different order than the order shown, or the operations may be performed in different orders or at different times. Certain operations may also be left out of the methods, one or more operations may be repeated, or other operations may be added.

Embodiments of the present disclosure support one or more processes (methods, flowcharts) supportive of the features and embodiments described herein. Descriptions that an element “may be disposed,” “may be formed,” and the like include processes (methods, flowcharts) and techniques for disposing, forming, positioning, and modifying the element, and the like, in accordance with example aspects described herein.

Referring to FIG. 3, the method of manufacturing the display device DD according to one or more embodiments of the present disclosure may include manufacturing the pixel circuit layer (S100), patterning the first electrode (S200), patterning the bank (S300), manufacturing the hole transport portion (S400), manufacturing the light emitting layer (S500), manufacturing the electron transport portion (S600), and forming the second electrode (S700).

Referring to FIG. 4, the manufacturing of the light emitting layer (S500) may include manufacturing the organic light emitting layer (S520), manufacturing the second quantum dot light emitting layer (S540), and manufacturing the first quantum dot light emitting layer (S560).

Referring to FIG. 3 and FIG. 5, in the manufacturing of the pixel circuit layer (S100), the method may include patterning the pixel circuits PXC on the base layer BSL and providing the pixel circuit layer PCL.

At step S100, the method may include disposing layers for forming the pixel circuit layer PCL on the base layer BSL. For example, the method may include patterning the first to third pixel circuits PXC1 to PXC3 on the base layer BSL.

In some embodiments, the method may include forming a conductive layer and an insulating layer on the base layer BSL based on a process (e.g., a general process) for manufacturing a semiconductor device. For example, the method may include forming the conductive layer or the insulating layer on the base layer BSL by a photolithography process, etching by various methods (wet etching, dry etching, and the like), and deposition by various methods (sputtering, chemical vapor deposition, and the like). However, embodiments of the present disclosure are not necessarily limited to the particular examples.

Referring to FIG. 3 and FIG. 5, in the patterning of the first electrode (S200), the method may include disposing the first electrodes ELT1 on the pixel circuit layer PCL such that the electrodes ELT1 are spaced apart from each other.

At step S200, the method may include patterning the (1-1)-th electrode ELT1-1, the (1-2)-th electrode ELT1-2, and the (1-3)-th electrode ELT1-3 for forming an anode electrode. Although not shown in FIG. 5, the (1-1)-th electrode ELT1-1, the (1-2)-th electrode ELT1-2, and the (1-3)-th electrode ELT1-3 may be electrically connected to the first to third pixel circuits PXC1 to PXC3, respectively.

Referring to FIG. 3 and FIG. 5, in the patterning of the bank (S300), the method may include disposing the bank BNK surrounding an area.

In some aspects, based on the patterning of the bank BNK at step S300, a space that may accommodate ink may be formed in the inkjet printing process for manufacturing the light emitting layer EL.

At step S300, the method may include patterning the bank BNK such that the bank BNK surrounds an area in a plan view and forms the opening (OPN). For example, the bank BNK may surround areas (for example, areas for forming the first to third light emitting elements LD1 to LD3) for forming the first to third sub-pixel areas SPXA1 to SPXA3, and accordingly, for example, the first to third openings OPN1 to OPN3 may be formed.

At step S300, the method may include forming the third opening OPN3 such that the third opening OPN3 is larger than each of the first and second opening OPN1 and OPN2. The second opening OPN2 may be formed such that the second opening OPN2 is larger than the first opening OPN1. In some embodiments, the size of each of the openings OPN may correspond to the aperture ratio of the corresponding sub-pixel area SPXA. Accordingly, for example, the aperture ratio of the third sub-pixel SPX3 may be greater than respective aperture ratios of the first and second sub-pixels SPX1 and SPX2, and the aperture ratio of the second sub-pixel SPX2 may be greater than the aperture ratio of the first sub-pixel SPX1.

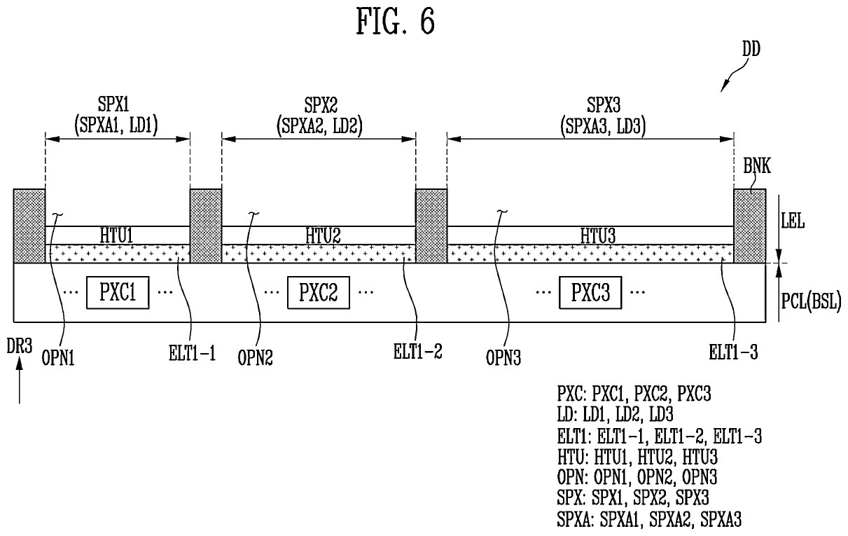

Referring to FIG. 3 and FIG. 6, in the manufacturing of the hole transport portion (S400), the method may include disposing respective hole transport portions HTU of the first to third sub-pixels SPX in the opening OPN.

At step S400, the method may include sequentially stacking two or more layers such that the two or more layers form the hole transport portion HTU. In some embodiments, the layers for forming the hole transport portion HTU may be disposed by various methods such as, for example, a vacuum deposition method, a spin coating method, a casting method, a Langmuir-Blodgett (LB) method, an inkjet printing method, a laser printing method, and laser induced thermal imaging (LITI) method.

At step S400, the method may include disposing the first hole transport portion HTU1 in the first opening OPN1, disposing the second hole transport portion HTU2 in the second opening OPN2, and disposing the third hole transport portion HTU3 in the third opening OPN3.

In some embodiments, at least some layers of the first to third hole transport portions HTU1 to HTU3 may be patterned in the same process (e.g., during the same patterning process and/or using the same patterning process). However, embodiments of the present disclosure are not limited thereto.

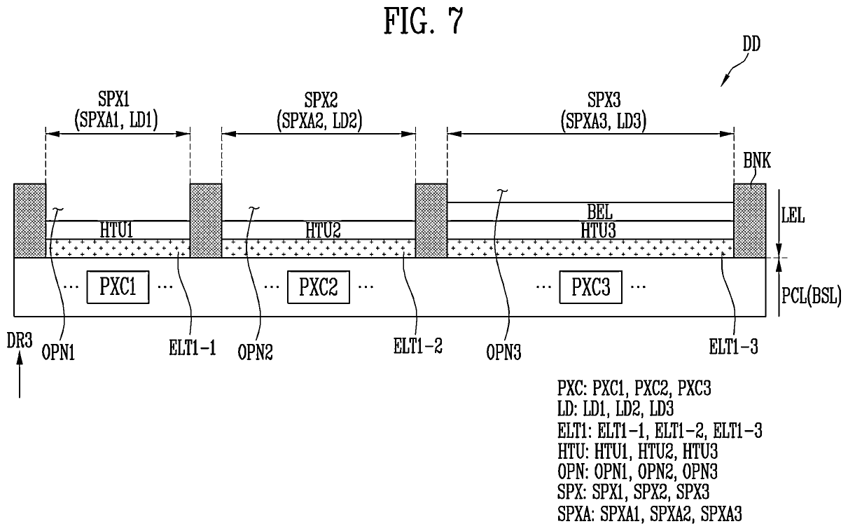

Referring to FIG. 3, FIG. 4, and FIG. 7, the manufacturing of the light emitting layer (S500) may include manufacturing of the organic light emitting layer (S520).

At step S520, the method may include patterning the organic light emitting layer BEL within the third opening OPN3.

In some embodiments, the method may include disposing the organic light emitting layer BEL by using an inkjet printing process. In some embodiments, the method may include using an inkjet printer including a nozzle configured to discharge fluid in association with performing the inkjet printing process described herein. For example, in association with providing the organic light emitting layer BEL, the method may include supplying ink for manufacturing an organic light emitting layer including an organic light emitting material and a solvent for manufacturing the third sub-pixel SPX3 to the third opening OPN3 corresponding to the third sub-pixel area SPXA3 (for example, overlapping the third sub-pixel area SPXA3). The organic light emitting layer BEL is a layer included in the third sub-pixel SPX3 and may be supplied to the third opening OPN3 forming an aperture ratio greater than respective aperture ratios of the first and second sub-pixels SPX1 and SPX2.

In some embodiments, the solvent included in the ink for manufacturing the organic light emitting layer may include an organic solvent. The solvent included in the ink for manufacturing the organic light emitting layer may include two or more solvents. The solvent included in the ink for manufacturing the organic light emitting layer may include various solvents having a boiling point smaller than the boiling point of the solvent included in the first and second quantum dot inks. For example, the solvent included in the ink for manufacturing the organic light emitting layer may include two or more solvents to have a boiling point smaller than the boiling point of the solvent included in the first and second quantum dot inks. For example, the solvent included in the ink for manufacturing the organic light emitting layer may include one or more of propylene glycol methyl ethyl acetate (PGMEA), dipropylene glycol-propyl ether (DGPE), and triethylene glycol-butyl ether (TGBE) with a boiling point smaller than the boiling point of the solvents included in the first and second quantum dot ink. However, embodiments of the present disclosure are not limited to the example described herein.

Referring to step S520, the method may include disposing the first and second quantum dot inks such that the first and second quantum dot inks are not disposed in the first and second openings OPN1 and OPN2.

In some embodiments, after the ink for manufacturing the organic light emitting layer is ejected, the method may include performing a drying process in association with manufacturing the organic light emitting layer BEL. The drying process may include a process in which the solvent is removed under a temperature range and a vacuum environment. For example, the temperature range may be 25° C. to 75° C. As the temperature range described herein is satisfied and the drying process is performed under the vacuum environment, the solvent may be effectively removed as long as the properties of the ejected material are not damaged.

In some embodiments, the ink for manufacturing the organic light emitting layer includes a solvent with a relatively low boiling point, and thus may have a lower boiling point than respective boiling points of the first and second quantum dot inks. Accordingly, for example, even when the ink for manufacturing the organic light emitting layer is discharged on the pixel circuit layer PCL at a relatively advanced time, sufficient drying may be performed within a time period substantially similar to the first and second quantum dot inks to be discharged later. Expressed another way, the method may include discharging the ink for manufacturing the organic light emitting layer onto the pixel circuit layer PCL according to a relatively fast discharge rate (e.g., above a threshold rate), but due to the boiling point of the solvent in the ink, the ink may be sufficiently dried within a time period substantially similar to the time period for drying the first and second quantum dot inks.

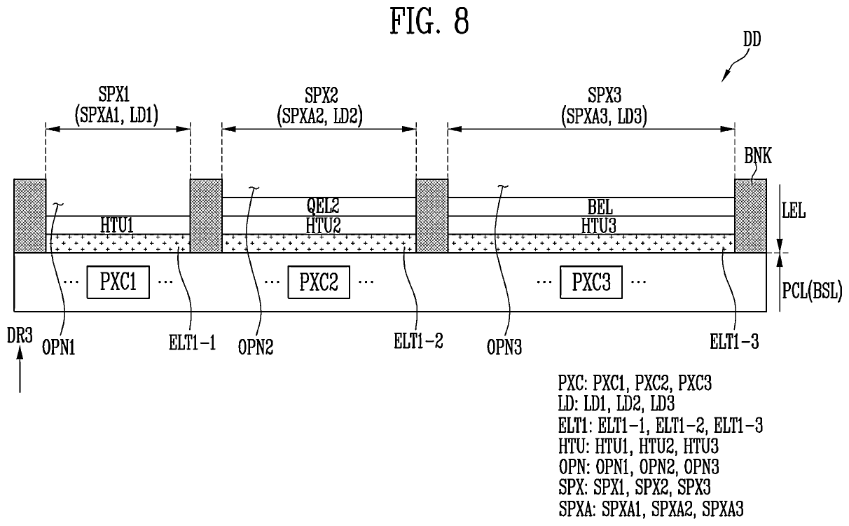

Referring to FIG. 3, FIG. 4, and FIG. 8, the manufacturing of the light emitting layer (S500) may include the manufacturing of the second quantum dot light emitting layer (S540).

In some embodiments, the method may include disposing the second quantum dot light emitting layer QEL2 by using an inkjet printing process. For example, in association with providing the second quantum dot light emitting layer QEL2, the method may include supplying the second quantum dot ink including a quantum dot compound and a solvent for manufacturing the second sub-pixel SPX2 to the second opening OPN2 corresponding to the second sub-pixel area SPXA2 (for example, overlapping the second sub-pixel area SPXA2). The second quantum dot light emitting layer QEL2 is a layer included in the second sub-pixel SPX2, and the method may include supplying the second quantum dot light emitting layer QEL2 to the opening OPN2 forming an aperture ratio that is smaller than the aperture ratio of the third sub-pixel SPX3 but larger than the aperture ratio of the first sub-pixel SPX1.

Referring to step S540, the method may include disposing the organic light emitting layer BEL and refraining from disposing the first quantum dot light emitting layer QEL1.

In some embodiments, after the second quantum dot ink is ejected, the method may include performing a drying process in association with manufacturing the second quantum dot light emitting layer QEL2. The drying process may include a process in which the solvent is removed under a temperature range and a vacuum environment. For example, the temperature range may be 25° C. to 75° C. In some aspects, performing the drying process according to the temperature range and under the vacuum environment may support effective removal of the solvent as long as the properties of the ejected material are not damaged. For example, performing the drying process according to the temperature range and under the vacuum environment may support preventing damage to the properties of the ejected material.

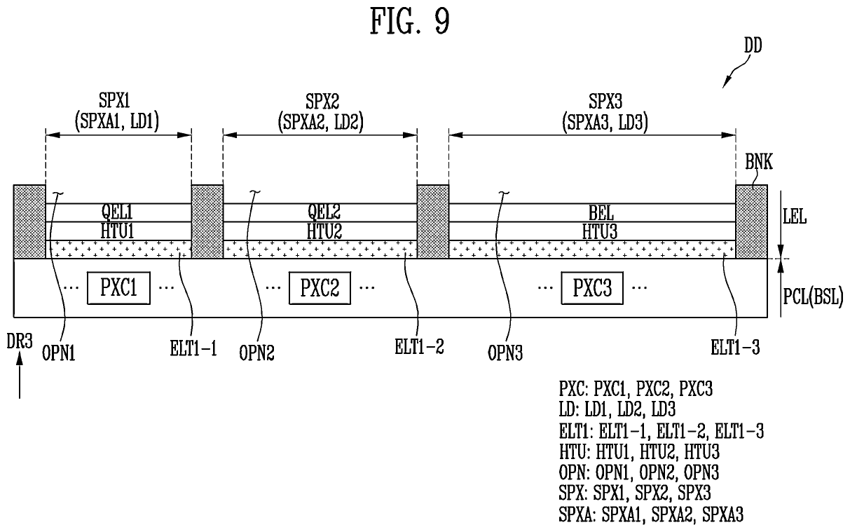

Referring to FIG. 3, FIG. 4, and FIG. 9, the manufacturing of the light emitting layer (S500) may include manufacturing of the first quantum dot light emitting layer (S560).

In some embodiments, the method may include disposing the first quantum dot light emitting layer QEL1 by using an inkjet printing process. For example, in association with providing the first quantum dot light emitting layer QEL1, the method may include supplying the first quantum dot ink including a quantum dot compound and a solvent for manufacturing the first sub-pixel SPX1 to the first opening OPN2 corresponding to the first sub-pixel area SPXA1 (for example, overlapping the first sub-pixel area SPXA1). The first quantum dot light emitting layer QEL1 is a layer included in the first sub-pixel SPX1, and the method may include supplying first quantum dot light emitting layer QEL1 to the first opening OPN1 forming an aperture ratio that is smaller than respective aperture ratios of the second and third sub-pixels SPX2 and SPX3.

Referring to step S560, the organic light emitting layer BEL and the second quantum dot light emitting layer QEL2 may be in a disposed state.

In some embodiments, after the first quantum dot ink is ejected, the method may include performing a drying process in association with manufacturing the first quantum dot light emitting layer QEL1. The drying process may include a process in which the solvent is removed under a temperature range and a vacuum environment. For example, the temperature range may be 25° C. to 75° C. As the temperature range described herein is satisfied and the drying process is performed under the vacuum environment, the solvent may be effectively removed as long as the properties of the ejected material are not damaged.

In some embodiments, the method may include performing a drying process after all of the first and second quantum dot inks are ejected. In this case, similar to the descriptions herein with respect to drying processes, the drying process may include a process in which a solvent is removed under a temperature range and a vacuum environment, and the temperature range may be 25° C. to 75° C.

In some embodiments, the solvent included in the first and second quantum dot inks may include an organic solvent. The solvent included in the first and second quantum dot inks may include two or more solvents. The solvent included in the first and second quantum dot inks may include various solvents having a higher boiling point than the solvent included in the ink for manufacturing the organic light emitting layer. For example, the solvent included in the first and second quantum dot inks may include two or more solvents each having a higher boiling point than the solvent included in the ink for manufacturing the organic light emitting layer. For example, the solvent included in each of the first and second quantum dot inks may include one or more independently selected from propylene glycol methyl ethyl acetate (PGMEA), dipropylene glycol-propyl ether (DGPE), and triethylene glycol-butyl ether (TGBE) having a boiling point higher than the boiling point of the solvent included in the ink for manufacturing the organic light emitting layer. However, embodiments of the present disclosure are not limited to the example described herein.

In some embodiments, the first and second quantum dot inks may have a higher boiling point than the ink for manufacturing the organic light emitting layer. Accordingly, for example, even when the first and second quantum dot inks are ejected into the first and second openings OPN1 and OPN2 within a later time period compared to the ink for manufacturing the organic light emitting layer, the time points of the completion of respective drying steps of the first and second quantum dot inks and the ink for manufacturing the organic light emitting layer may be substantially similar. Expressed another way, due to the respective boiling points (and resulting drying times) associated with the first and second quantum dot inks and the ink for manufacturing the organic light emitting layer, the drying times associated with the first and second quantum dot inks may be less than the drying time associated with the ink for manufacturing the organic light emitting layer. For cases described herein in which the first and second quantum dot inks are dispersed (e.g., ejected or discharged) at an earlier time point compared to the dispersal (e.g., ejection, discharge) of the ink for manufacturing the organic light emitting layer, the first quantum dot ink, the second quantum dot ink, and the ink for manufacturing the organic light emitting layer may be completely dry at substantially the same time point.

In some aspects, as the drying time for the solvent of the first and second quantum dot inks is reduced, the risk of the dried solvent damaging the organic material included in the organic light emitting layer BEL may be reduced.

In some aspects, as discussed above, the ink for manufacturing the organic light emitting layer that is ejected relatively early may have a lower boiling point than respective boiling points of the first and second quantum dot inks that are ejected within a relatively later time period. Experimentally, when the inkjet printing process is performed, as some of the solvent in the previously ejected ink is dried, the dried solvent may affect the thickness formation of the light emitting layer EL in another area adjacent the light emitting layer EL. However, according to one or more embodiments of the present disclosure, the boiling point of the previously discharged ink for manufacturing the organic light emitting layer may be low (e.g., below a threshold value), and in this case, the risk of the ink for manufacturing the organic light emitting layer affecting the thickness formation of the light emitting layer EL in another area may be reduced. As a result, the process order and ink properties may be specifically designed based on material properties, and the thickness of the light emitting layers EL according to one or more embodiments of the present disclosure may be properly defined based on the intended thickness range.

In some aspects, as the first and second quantum dot inks with high boiling points are ejected into the relatively narrow first and second openings OPN1 and OPN2, the amount of dried solvent of the first and second quantum dot inks is reduced, and likewise, the risk of the dried solvent damaging the organic materials included in the organic light emitting layer BEL may be reduced.

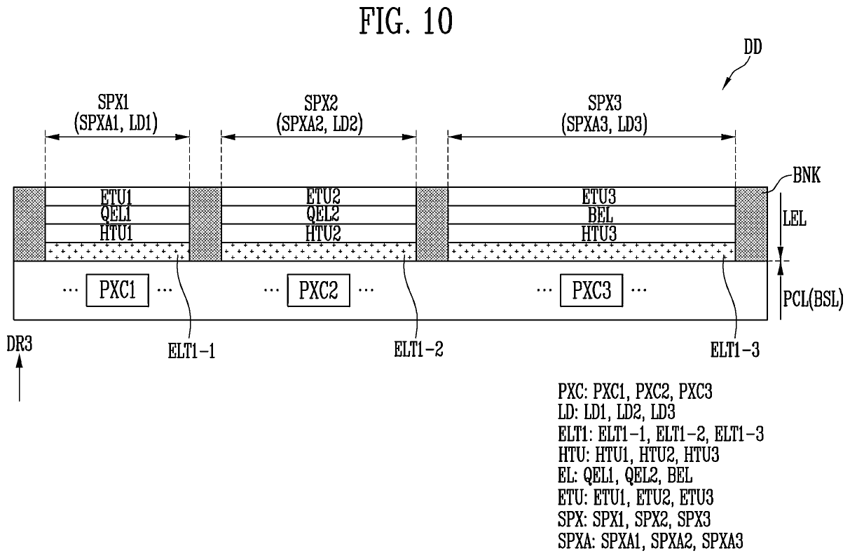

Referring to FIG. 3 and FIG. 10, the manufacturing of the electron transport portion (S600) may include disposing respective electron transport portions ETU of the first to third sub-pixels SPX in the opening OPN.

At step S600, the method may include sequentially stacking two or more layers in association with forming the electron transport portion ETU. In some embodiments, the layers for forming the electron transport portion ETU may be disposed by various methods such as, for example, a vacuum deposition method, a spin coating method, a casting method, a Langmuir-Blodgett (LB) method, an inkjet printing method, a laser printing method, and laser induced thermal imaging (LITI) method.

At step S600, the method may include disposing the first electron transport portion ETU1 in the first opening OPN1, disposing the second electron transport portion ETU2 in the second opening OPN2, and disposing the third electron transport portion ETU3 in the third opening OPN3.

In some embodiments, at least some layers of the first to third electron transport portions ETU1 to ETU3 may be patterned in the same process (e.g., during the same patterning process and/or using the same patterning process). However, embodiments of the present disclosure are not limited thereto.

Referring to FIG. 3 together with FIG. 2, the forming of the second electrode (S700) may include forming the second electrode ELT2 forming a cathode electrode.

At step S700, the method may include preparing the first to third light emitting elements LD1 to LD3 formed in the first to third sub-pixel areas SPXA1 to SPXA3.

Thereafter, according to one or more embodiments of the present disclosure, the method may include disposing additional layers (a window and the like) on the light emitting element layer LEL, and the display device DD according to one or more embodiments of the present disclosure may be manufactured.

While the present disclosure has been shown and described with reference to certain embodiments supported by aspects of the present disclosure, it will be understood by those skilled in the art that various changes in forms and details may be made therein without departing from the spirit and scope of the present disclosure as defined by the appended claims and their equivalents.

Therefore, the technical scope of the present disclosure may be determined by on the technical scope of the accompanying claims.

What is claimed is:

1. A display device comprising:
sub-pixels comprising a first sub-pixel forming a first sub-pixel area providing light of a first color, a second sub-pixel forming a second sub-pixel area providing light of a second color, and a third sub-pixel forming a third sub-pixel area providing light of a third color,
wherein:
the third sub-pixel area is larger than each of the first sub-pixel area and the second sub-pixel area,
each of the first sub-pixel and the second sub-pixel comprises a quantum dot light emitting element including a quantum dot light emitting layer, and
the third sub-pixel comprises an organic light emitting element including an organic light emitting element layer.

2. The display device of claim 1, wherein:
the second sub-pixel area is larger than the first sub-pixel area,
the first sub-pixel is a red sub-pixel,
the second sub-pixel is a green sub-pixel, and
the third sub-pixel is a blue sub-pixel.

3. The display device of claim 1, wherein
the quantum dot light emitting layer included in the quantum dot light emitting element comprised in the first sub-pixel comprises a first quantum dot light emitting layer,
the quantum dot light emitting layer included in the quantum dot light emitting element comprised in the second sub-pixel comprises a second quantum dot light emitting layer, and
the organic light emitting layer, the first quantum dot light emitting layer, and the second quantum dot light emitting layer are of a same thickness.

4. The display device of claim 1, further comprising
a bank surrounding a first area in which the quantum dot light emitting layer and the organic light emitting element of the first sub-pixel are disposed and a second area in which the quantum dot light emitting layer and the organic light emitting element of the second sub-pixel are disposed,
wherein the bank forms a first opening that overlaps the first sub-pixel area, a second opening that overlaps the second sub-pixel area, and a third opening that overlaps the third sub-pixel area.

5. The display device of claim 1, wherein:
the quantum dot light emitting layer comprises a quantum dot compound, and
the organic light emitting layer comprises an organic material.

6. The display device of claim 1, wherein
each of the quantum dot light emitting element comprised in the first sub-pixel, the quantum dot light emitting element comprised in the second sub-pixel, and the organic light emitting element further comprises a first electrode, a hole transport portion, an electron transport portion, and a second electrode.

7. A method of manufacturing a display device, wherein the display device comprises sub-pixels including a first sub-pixel forming a first sub-pixel area providing light of a first color, a second sub-pixel forming a second sub-pixel area providing light of a second color, and a third sub-pixel forming a third sub-pixel area providing light of a third color, the method comprising:
manufacturing a pixel circuit layer;
patterning a bank on the pixel circuit layer; and
manufacturing a light emitting layer within one or more openings formed by the bank,
wherein:
the one or more openings comprise a first opening in the first sub-pixel area, a second opening in the second sub-pixel area, and a third opening in the third sub-pixel area,
the manufacturing of the light emitting layer includes:
manufacturing an organic light emitting layer within the third opening;
manufacturing a second quantum dot light emitting layer within the second opening; and
manufacturing a first quantum dot light emitting layer within the first opening,
a third area of the third opening is larger than each of a first area of the first opening and a second area of the second opening in a plan view, and
the manufacturing of the organic light emitting layer is performed before the manufacturing of the first quantum dot light emitting layer and the manufacturing of the second quantum dot light emitting layer.

8. The method of claim 7, wherein the manufacturing of the light emitting layer comprises performing an inkjet printing process.

9. The method of claim 8, wherein:
the manufacturing of the organic light emitting layer comprises ejecting ink for manufacturing the organic light emitting layer onto the pixel circuit layer,
the manufacturing of the first quantum dot light emitting layer comprises ejecting a first quantum dot ink onto the pixel circuit layer, and
the manufacturing of the second quantum dot light emitting layer comprises ejecting a second quantum dot ink onto the pixel circuit layer.

10. The method of claim 9, wherein the first quantum dot ink and the second quantum dot ink comprise a same solvent.

11. The method of claim 9, wherein each of the first quantum dot ink, the second quantum dot ink, and the ink for manufacturing the organic light emitting layer comprises two or more solvents.

12. The method of claim 9, wherein each of the first quantum dot ink, the second quantum dot ink, and the ink for manufacturing the organic light emitting layer comprises an organic solvent.

13. The method of claim 9, wherein a boiling point of the ink for manufacturing the organic light emitting layer is lower than respective boiling points of the first quantum dot ink and the second quantum dot ink.

14. The method of claim 9, wherein:
the manufacturing of the light emitting layer comprises drying a solvent of each of the first quantum dot ink, the second quantum dot ink, and the ink for manufacturing the organic light emitting layer, and
the drying of the solvent is performed in a temperature range of 25° C. to 75° C. and in a vacuum environment.

15. The method of claim 7, wherein:
the manufacturing of the second quantum dot light emitting layer is performed after the manufacturing of the organic light emitting layer is performed, and
the manufacturing of the first quantum dot light emitting layer is performed after the manufacturing of the second quantum dot light emitting layer is performed.

16. The method of claim 7, wherein:
each of the first quantum dot light emitting layer and the second quantum dot light emitting layer comprises a quantum dot compound,
the organic light emitting layer comprises an organic material, and
the organic light emitting layer, the first quantum dot light emitting layer, and the second quantum dot light emitting layer are of a same thickness.
